(19) United States
(12) Patent Application Publication
(10) Pub. No.: US 2002/0199130 A1
(43) Pub. Date: Dec. 26, 2002

(54) Automatic address redirecting memory device and the method of the same

(76) Inventor: Yao-Jung Kuo, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/883,928

(22) Filed: Jun. 20, 2001

(51) Int. Cl. G06F 12/16; H03K 19/003

(52) U.S. Cl. 714/8

(57) ABSTRACT

A method for automatically redirecting addresses of defect cells in a memory comprises the steps of: detecting at least one defect cell in a memory; recording an address of the defect cell into a memory defect circuit; and redirecting the address of the detect cell into a new perfect cell and then stored the relation of the address and the new cell. Another, an automatic address redirecting memory device is disclosed. The device comprises an automatic detecting circuit having one end connected to the central processing unit, and another end connected to the memory for automatically detecting the addresses of the defect cells in the memory; a memory defect circuit connected to the automatic detecting circuit for recording the addresses of the defect cells to the memory; and an address redirecting circuit connected between the memory defect circuit and the central processing unit for converting the defect address into a circuit. Therefore, as the memory has defects, than the user may use the present invention to use the memory continuously without needing to stop the equipment.

### FIELD OF THE INVENTION

The present invention relates to an automatic address redirecting memory device and the method of the same, and especially to a circuit, in that an automatic detecting circuit is used to detect the defects in a memory and then the address of the defect is recorded. Therefore, in practical using, the user uses the memory as no defect.

### BACKGROUND OF THE INVENTION

Currently, memories are widely used to various electronic devices. However, despite of the kinds of memories, such as EERPOM, FLASH, MEMORY, SRAM, DRAM, etc, a large amount of power and complex processes are necessary so that the prices are high, while this becomes a larger burden to the users. Conventionally, once some addresses of a memory have defects, then the memory can not be used. Conventionally, a software is used to search for the defect addresses and then the address is redirected to another cell in the memory so that a new perfect memory is formed. In general, this is hard to users. It must be performed by professional workers with professional software. It is time-consuming work and needs novel technology which can not be performed by those not skilled in the art.

Therefore, an automatic address redirecting memory device and the method of same are provided. Thereby, not only the destroyed memory can be reused automatically without needing to update a new memory, but also the system related to this memory need not be stopped.

### SUMMARY OF THE INVENTION

Accordingly, the primary object of the present invention is to provide a device and method for automatically redirecting addresses of defect cells in a memory, wherein as a memory has defect, by the present invention, the user may user other normal portion of the memory without needing to update the memory.

Another object of the present invention is to provide a device and method for automatically redirecting addresses of defect cells in a memory, wherein the user may use the present invention easily and conveniently with a lower cost.

A further object of the present invention is to provide a device and method for automatically redirecting addresses of defect cells in a memory, wherein an automatic address redirecting device is installed between two memory and a central processing unit. Thereby the defect addresses in the memory can be detected and then recorded so that next time when data is wanted to be written, the defect cell will not be used.

The various objects and advantages of the present invention will be more readily understood from the following detailed description when read in conjunction with the appended drawing.

### BRIEF DESCRIPTION OF THE DRAWINGS

FIG. 1 is a block diagram of a preferred embodiment of the present invention.

FIG. 2 is a flow diagram of a preferred embodiment about the operation of the present invention.

### DETAILED DESCRIPTION OF THE PREFERRED EMBODIMENTS

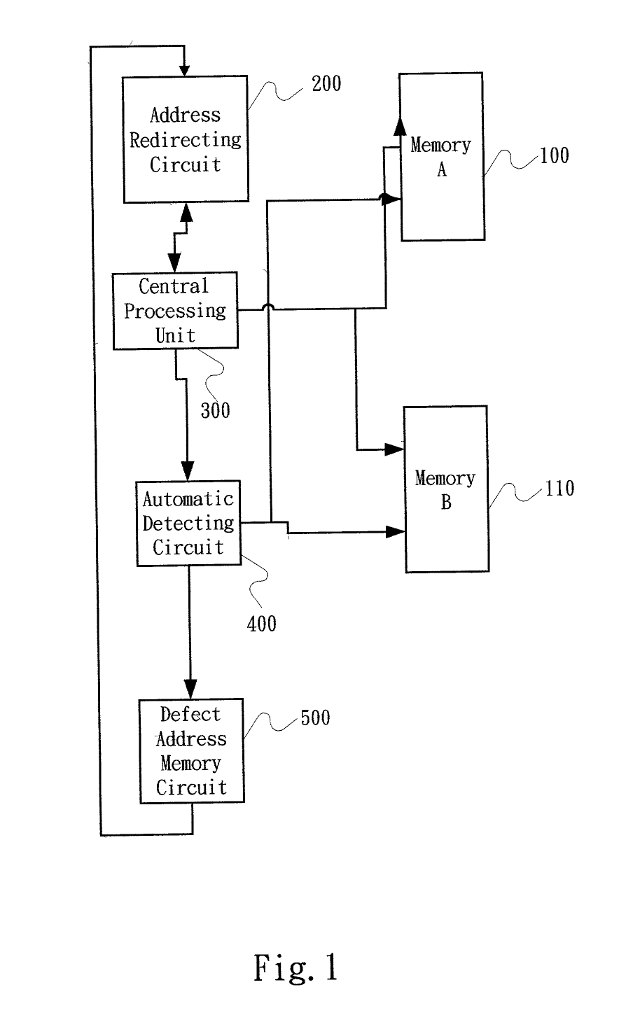

Referring to FIG. 1, the block diagram of a preferred embodiment is illustrated. As shown in the figure, in the automatic address redirecting memory device of the present invention, an automatic address redirector is connected to two memories 100, 110 and a central processing unit. This automatic address redirector includes an automatic detecting circuit 400 connected to the central processing unit 300 and the memories 100, 110 for detecting the defect address of the memories 100, 110. The automatic detecting circuit 400 is connected to a memory defect circuit 500 for recording the defect addresses. Furthermore, an address redirecting circuit is connected between the memory defect circuit 500 and the central processing unit 300 for redirecting an address to a normal cell. Therefore, when central processing unit 300 is in reading or input data, when address defects occur in a memory A100 and a memory B110. The central processing unit 300 will automatically actuate the automatic detecting circuit 400 for scanning memories A110 and B110. When the defect address is detected, the memory defect circuit 500 will record the address on the defect memory address table. Then the address redirecting circuit is used to convert the defect address into a circuit and transfers the address to the central processing unit 300 as a reference. When the central processing unit 300 accesses data, it will write data into the normal address in the memory instead of the defect cell according to the address redirecting circuit 200.

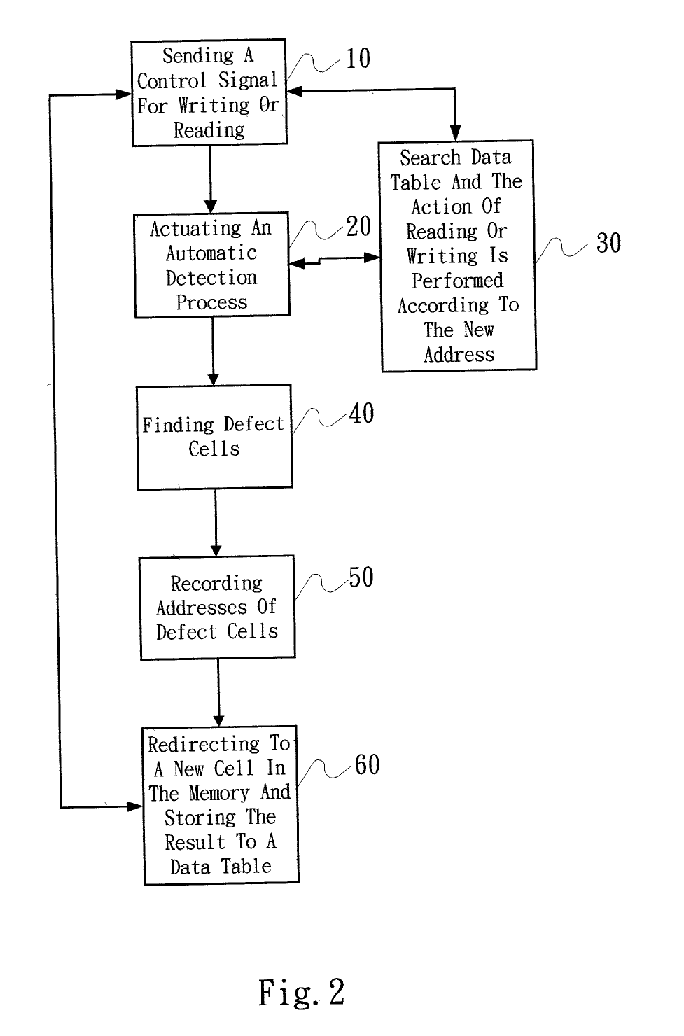

With reference to FIG. 2, a flow diagram of a preferred embodiment of the present invention is illustrated. As shown in the figure, in step 10, the central processing unit sends a control signal for writing or reading. Then the processes enters into step 20, wherein an automatic detection process is actuated. Then, the process enters into step 40. In step 40, the defect cells are searched in the memory. In step 50, the addresses of the defect cells are recorded in the memory. Then, in step 60, the address original assigned to the defect cell is redirected to a new cell in the memory. Then, these new addresses are stored in a data table. As a data to be read or write to the memory, then the CPU will firstly search data table (step 30) and the action of reading or writing is performed according to the new address so as to avoid the defect cell.

In summary, in the automatic address redirecting memory device of the present invention, and the method of the same, an address about defect cell is detected and then is recorded so that the perfect addresses can be used and the destroyed addresses are avoided. Therefore, the memory is unnecessary to be updated. The use is convenient and no updating operation is required, and thus other related equipment may be operated continuously. As a result, cost is down.

The present invention are thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An automatic address redirecting memory device having an automatic address redirector connected between at least one memory and at least one central processing unit; the automatic address redirector comprising:
an automatic detecting circuit having one end connected to the central processing unit, and another end connected to the memory for automatically detecting the addresses of the defect cells in the memory;
a memory defect circuit connected to the automatic detecting circuit for recording the addresses of the defect cells to the memory; and
an address redirecting circuit connected between the memory defect circuit and the central processing unit for converting the defect address into a circuit.

2. The automatic address redirecting memory device as claimed in claim 2, wherein the redirected address is provided to the central processing unit as a basis when data is stored to the memory.

3. A method for automatically redirecting addresses of defect cells in a memory comprising the steps of:
detecting at least one defect cell in a memory;
recording an address of the defect cell into a memory defect circuit; and
redirecting the address of the detect cell into a new perfect cell and then stored the relation of the address and the new cell.

4. The method as claimed in claim 3, wherein in detecting the memory, as a defect cell is detected, then in the next time, the memory is actuated, this defect cell will not be searched.

5. The method as claimed in claim 3, wherein a result about the detection of the memory is recorded.
